(19) United States
(12) Patent Application Publication
(10) Pub. No.: US 2026/0196803 A1
(43) Pub. Date: Jul. 9, 2026

(54) LASER DIODE COMPONENT AND METHOD FOR PRODUCING A LASER DIODE COMPONENT

(71) Applicant: ams-OSRAM International GmbH, Regensburg (DE)

(72) Inventors: Norwin VON MALM, Nittendorf (DE); Hubert HALBRITTER, Dietfurt (DE); Åsa HAGLUND, Göteborg (SE); Joachim CIERS, Göteborg (SE); Andreas LIUDI MULYO, Göteborg (SE)

(21) Appl. No.: 19/133,137

(22) PCT Filed: Nov. 15, 2023
(86) PCT No.: PCT/EP2023/081902

§ 371 Date: May 27, 2025

(30) Foreign Application Priority Data
Nov. 28, 2022 (DE) 10 2022 131 374.3

(51) Int. Cl. H01S 5/042; H01S 5/183

(52) U.S. Cl. CPC H01S 5/0421; H01S 5/18308

(57) ABSTRACT

A laser diode component includes a semiconductor layer stack including: a first semiconductor region, a second semiconductor region and an active region. the first semiconductor region has a projecting area, where the first semiconductor region laterally projects beyond the active region and the second semiconductor region. The laser diode component also includes a dielectric layer covering the semiconductor layer stack, and first contact means for electrically contacting the first semiconductor region. The first contact means includes a first contact layer covering the projecting area of the first semiconductor region, and a first contact post. The laser diode component further includes second contact means for electrically contacting the second semiconductor region. The second contact means includes a second contact post. A first contact area of the first contact post laterally surrounds a second contact area of the second contact post.

A laser diode component and a method for producing a laser diode component are specified. For example, the laser diode component is a thin film VCSEL (Vertical-Cavity Surface-Emitting Laser).

For example, there are known ultraviolet radiation emitting thin film VCSELs, which comprise a semiconductor layer stack between two dielectric distributed Bragg mirrors and are optically pumped. While the optically pumped thin film VCSEL may suffer from larger component size, an electrically pumped VCSEL has to deal, for example, with thermo-mechanical stress due to contact schemes provided for electrically contacting the VCSEL.

It is an object to specify a laser diode component providing improved reliability. This object is achieved inter alia by the laser diode component according to the independent claim. Further embodiments and further developments of the laser diode component are the subject-matter of the dependent claims.

It is another object to specify a method for producing a laser diode component that enables higher manufacturing yields. This object is achieved inter alia by the method according to the independent claim. Further embodiments and further developments of the method for producing a laser diode component are the subject-matter of the dependent claims.

According to at least one embodiment of a laser diode component, it comprises a semiconductor layer stack including a first semiconductor region, which may be of a first conductivity type, for example an n-doped semiconductor region, including a second semiconductor region, which may be of a second conductivity type, for example a p-doped semiconductor region and including an active region for emitting laser radiation, wherein the active region is arranged between the first semiconductor region and the second semiconductor region. For example, the laser diode component is suitable for emitting laser radiation having a wavelength in the ultraviolet to blue spectral range.

The active region may comprise a sequence of single layers which form a quantum well structure, in particular a single quantum well (SQW) structure or multiple quantum well (MQW) structure. Moreover, the first and second semiconductor regions may each have a sequence of single layers, some of which may be undoped or lightly doped.

The single layers of the semiconductor regions may be epitaxially deposited on a growth substrate.

Materials based on arsenide, phosphide or nitride compound semiconductors, for example, are suitable for the semiconductor regions or single layers of the semiconductor layer stack. “Based on arsenide, phosphide or nitride compound semiconductors” means in the present context that the semiconductor layers contain AlₙGaₘIn₁₋ₙ₋ₘAs, AlₙGaₘIn₁₋ₙ₋ₘP, or AlₙGaₘIn₁₋ₙ₋ₘN, where 0≤n≤1, 0≤m≤1 and n+m≤1. This material does not necessarily have to have a mathematically exact composition according to the above formula. Rather, it may have one or more dopants as well as additional constituents that do not substantially change the characteristic physical properties of the AlₙGaₘIn₁₋ₙ₋ₘAs, AlₙGaₘIn₁₋ₙ₋ₘP or AlₙGaₘIn₁₋ₙ₋ₘN material. For simplicity, however, the above formula includes only the essential constituents of the crystal lattice (Al, Ga, In, As or P or N, respectively), even though these may be partially replaced by small amounts of other substances. A quinternary semiconductor consisting of Al, Ga, In (group III) and P and As (group V) is also conceivable.

According to at least one embodiment, the first semiconductor region has a projecting area, where the first semiconductor region laterally projects beyond the active region and the second semiconductor region. “Laterally” means in one or more lateral directions, wherein the one or more lateral directions are parallel to a main extension plane of the semiconductor layer stack.

According to at least one embodiment, the laser diode component comprises a dielectric layer covering the semiconductor layer stack. For example, the dielectric layer is arranged on opposite surfaces of the semiconductor layer stack and sandwiches the active region. The dielectric layer may be a multilayer comprising at least two sublayers of different dielectric materials having different refractive indices. Suitable materials for the dielectric layer or the sublayers are dielectric materials like titanium oxide and silicon dioxide.

According to at least one embodiment, the laser diode component comprises first contact means for electrically contacting the first semiconductor region and second contact means for electrically contacting the second semiconductor region.

For example, the first contact means comprises a first contact layer, which covers the projecting area of the first semiconductor region. The first contact layer may electrically contact the first semiconductor region. The first contact layer may be a metallic layer formed from a metal or metal composition. The first contact means may further comprise a first contact post, which is arranged on a side of the first contact layer facing away from the first semiconductor region. The first contact post may electrically contact the first contact layer. The first contact post may be a metallic multilayer formed from one or more metals or metal compositions. For example, the first contact post may comprise a metal layer made of Ni, for example, and a first contact area containing Au, for example. The first contact post may be thicker than the first contact layer. The metal layer may have a thickness between 5 and 100 μm, preferably between 10 and 50 μm, most preferably between 20 and 30 gym.

The second contact means comprises, for example, a terminal layer partly covering the second semiconductor region. For example, the terminal layer is formed from a TOO (Transparent Conductive Oxide) and/or includes a semiconductor tunnel junction. The terminal layer may be designed to have low optical absorption. The terminal layer may be arranged in a vertical direction between the dielectric layer and the second semiconductor region. The vertical direction may be parallel to a radiation emitting direction.

The second contact means may further comprise a second contact layer laterally surrounding the terminal layer.

Furthermore, the second contact layer may partly laterally overlap with the terminal layer. For example, the second contact layer is a metallic layer formed from a metal or metal composition. The second contact layer may electrically contact the terminal layer.

Moreover, the second contact means may comprise a second contact post, which is arranged on a side of the second contact layer facing away from the second semiconductor region. The second contact post may be a metallic single layer or multilayer formed from one or more metals or metal compositions. For example, the second contact post may comprise an Ni layer and a second contact area containing Au, for example. The second contact post may be thicker than the second contact layer. The second contact post may electrically contact the second contact layer.

According to at least one embodiment, the first contact area of the first contact post laterally surrounds the second contact area of the second contact post. Moreover, the first contact post may laterally surround the second contact post. It is possible that the first contact area or first contact post does not completely laterally surround the second contact area or second contact post. The first contact area and the second contact area may be arranged in a common contact plane. For example, the common contact plane is arranged on a side of the active region opposite to a radiation exit side of the laser diode component. Thus, the laser diode component has a flip-chip design.

According to at least one embodiment of a laser diode component, it comprises:
a semiconductor layer stack comprising:
   a first semiconductor region,
a second semiconductor region and
an active region for emitting laser radiation, wherein the active region is arranged between the first semiconductor region and the second semiconductor region, and wherein the first semiconductor region has a projecting area, where the first semiconductor region laterally projects beyond the active region and the second semiconductor region,
a dielectric layer covering the semiconductor layer stack,
first contact means for electrically contacting the first semiconductor region, comprising:
   a first contact layer covering the projecting area of the first semiconductor region, and
   a first contact post, which is arranged on a side of the first contact layer facing away from the first semiconductor region,
second contact means for electrically contacting the second semiconductor region, comprising:
   a terminal layer partly covering the second semiconductor region,
   a second contact layer laterally surrounding the terminal layer, and
   a second contact post, which is arranged on a side of the second contact layer facing away from the second semiconductor region, wherein
      a first contact area of the first contact post laterally surrounds a second contact area of the second contact post.

According to at least one embodiment or configuration, the first contact post and the second contact post are spaced apart by a separation trench. For example, the separation trench has a rotationally symmetrical shape with respect to a centre axis of the laser diode component. The separation trench may have the shape of a circular ring. Advantageously, the rotationally symmetrical shape of the separation trench helps to balance the thermomechanical stress and thus reduce the risk of damages.

According to at least one embodiment or configuration, the first contact area and the second contact area each have a symmetrical shape, for example rotationally symmetrical shape with respect to a centre axis of the laser diode component. The shape of the first contact area may be symmetrical, but may slightly deviate from a rotationally symmetrical shape in an area where a second device electrode is supposed to be arranged to contact the second contact area.

For example, the second contact area has a circular shape. Furthermore, the first contact area may have a circular or almost circular edge facing the second contact area and may have a rectangular or almost rectangular edge facing away from the second contact area.

The symmetrical, for example rotationally symmetrical, shape of the contact areas assures superior robustness of the laser diode component.

According to at least one embodiment or configuration, the second contact layer and the terminal layer each have a rotationally symmetrical shape with respect to the centre axis of the laser diode component, for example a circular or circular ring shape. However, the shape of the first contact layer may slightly deviate from a rotationally symmetrical shape. For example, the first contact layer may have a circular inner edge and a rectangular outer edge, wherein a corner of the outer edge is cut off. At this cut-off corner, a sacrificial layer of a semiconductor layer sequence provided for producing the semiconductor layer stack is accessible, as will be explained below in more detail.

According to at least one embodiment or configuration, the laser diode component comprises an insulating layer, wherein the insulating layer partly covers the second semiconductor region and comprises an opening, where the terminal layer is arranged and contacts the second semiconductor region. In the final component, the insulating layer may serve as a current confinement layer for laterally confining a current flow through the semiconductor layer stack. For example, the insulating layer is formed from a transparent, electrically insulating material like SiO2.

According to at least one embodiment or configuration, the second semiconductor region and the active region do not laterally project beyond the insulating layer. Especially, a lateral extension and shape of the second semiconductor region and the active region is determined by the insulating layer. During the manufacturing process, the insulating layer may serve as a mask layer for patterning the semiconductor layer sequence in such a way that the semiconductor layer stack has the first semiconductor region laterally projecting beyond the second semiconductor region and the active region. The insulating layer may have the shape of a circular ring. Hence, the second semiconductor region and the active region may have a circular side edge, whereas the first semiconductor region may have a rectangular side edge.

According to at least one embodiment or configuration, the dielectric layer is arranged at least partly on all outer surfaces of the semiconductor layer stack. An outer surface is meant to be understood as a surface of the semiconductor layer stack which delimits the semiconductor layer stack to the outside and is not arranged within the semiconductor layer stack. In other words, the semiconductor layer stack may be arranged inside the dielectric layer. An outer surface may be a first main surface, a second main surface or side surface of the semiconductor layer stack.

According to at least one embodiment or configuration, the dielectric layer forms a laser resonator of the laser diode component. Especially, a first part of the dielectric layer and a second part of the dielectric layer arranged on opposite sides of the active region may constitute the laser resonator. Each of the first and second parts of the dielectric layer may constitute a DBR (Distributed Bragg Reflector) mirror. For example, a thickness of the semiconductor layer stack is optimized to form an optical cavity between the first and second parts of the dielectric layer.

According to at least one embodiment or configuration, the dielectric layer comprises a first recess and a second recess, and the first contact means is partly arranged in the first recess and the second contact means is partly arranged in the second recess. Moreover, the dielectric layer may comprise an aperture at a side surface of the semiconductor layer stack. Especially, the aperture is in the region of the above-mentioned cut-off corner.

According to at least one embodiment or configuration, the laser diode component comprises a mirror layer, which may be metallic and contain Al or Ag, for example. The mirror layer may be arranged on a side of the dielectric layer facing away from the terminal layer and may laterally overlap with the terminal layer.

According to at least one embodiment or configuration, the laser diode component comprises a carrier including first connection means and second connection means, wherein a first connection area of the first connection means is connected to the first contact area of the first contact means and a second connection area of the second connection means is connected to the second contact area of the second contact means. For example, the first connection area laterally surrounds at least partly the second connection area. Especially, the shape of the first connection area essentially matches the shape of the first contact area, and the shape of the second connection area essentially matches the shape of the second contact area.

According to at least one embodiment or configuration, the carrier comprises a carrier substrate formed from a material matching the coefficient of thermal expansion of the material of the semiconductor layer stack like for example silicon, ceramics or suitable metal materials. The first connection area and the second connection area may be arranged on a side of the carrier substrate facing the semiconductor layer stack. Other parts of the first and second connection means may be arranged inside the carrier substrate and/or on a side of the carrier substrate facing away from the semiconductor layer stack.

According to at least one embodiment or configuration, the semiconductor layer stack is arranged on the carrier in such a way that the second semiconductor region faces the carrier. The carrier may be arranged at a rear side of the laser diode component.

According to at least one embodiment or configuration, the laser diode component comprises a first device electrode and a second device electrode for electrically contacting the laser diode component from outside, wherein the first device electrode is a part of the first connection means and the second device electrode is a part of the second connection means.

According to at least one embodiment or configuration, the laser radiation is emitted mainly at a front side of the laser diode component facing away from the carrier. Hence, the front side is the radiation exit side of the laser diode component. For example, the laser diode component is a VCSEL.

According to at least one embodiment or configuration, the semiconductor layer stack is essentially free of a growth substrate. In other words, the laser diode component may be a thinfilm device. “Essentially free” means that the growth substrate is missing or remains only in parts. The thinfilm design of the laser diode component delivers superior device efficiency.

In the following, embodiments or configurations of a method are described that are suitable for producing a laser diode component as mentioned above. This means that all features described in connection with the laser diode component apply to the method as well, and vice versa.

According to at least one embodiment of a method, it comprises the following steps:
providing a semiconductor layer sequence for producing at least one semiconductor layer stack, the semiconductor layer sequence comprising:
a first semiconductor layer,
a second semiconductor layer and
an active layer for emitting laser radiation, wherein the active layer is arranged between the first semiconductor layer and the second semiconductor layer,
applying a mask layer on parts of the second semiconductor layer,
applying a terminal layer structure on parts of the second semiconductor layer for producing at least one terminal layer,
patterning the semiconductor layer sequence by means of the mask layer in such a way that the first semiconductor layer has at least one projecting area, where the first semiconductor layer laterally projects beyond the active layer and the second semiconductor layer,
applying a contact layer structure for producing at least one first contact layer and at least one second contact layer on the at least one projecting area of the first semiconductor layer and on the second semiconductor layer in such a way that the contact layer structure laterally surrounds the terminal layer structure,
applying a first dielectric layer structure on the semiconductor layer sequence in order to produce a first part of at least one dielectric layer,
applying a contact post structure on the first dielectric layer structure in such a way that a first contact area of at least one first part of the contact post structure provided for producing at least one first contact post laterally surrounds a second contact area of at least one second part of the contact post structure provided for producing at least one second contact post.

The first semiconductor layer is provided for producing a first semiconductor region of the at least one semiconductor layer stack and thus may correspond to the first semiconductor region with respect to its layer structure and/or with respect to its material composition as mentioned above. The second semiconductor layer is provided for producing a second semiconductor region of the at least one semiconductor layer stack and thus may correspond to the second semiconductor region especially with respect to its layer structure and/or material composition as mentioned above. And the active layer is provided for producing an active region of the at least one semiconductor layer stack and thus may correspond to the active region especially with respect to its layer structure and/or material composition as mentioned above.

According to at least one embodiment or configuration, the semiconductor layer sequence is provided on a growth substrate, for example a GaN growth substrate. The first semiconductor layer may be arranged facing the growth substrate, whereas the second semiconductor layer may be arranged facing away from the growth substrate.

According to at least one embodiment or configuration, the semiconductor layer sequence, for example the first semiconductor layer, comprises a highly doped sacrificial layer facing the growth substrate. For example, the sacrificial layer is n-doped, for example with Si. Moreover, the sacrificial layer may have a doping concentration of 2×10¹⁸ to 10²⁰ cm⁻³, especially 8×10¹⁸ to 2×10¹⁹ cm⁻³. For example, the sacrificial layer is followed by a semiconductor layer having a lower doping concentration on a side facing away from the growth substrate.

According to at least one embodiment or configuration, the step of applying the mask layer is conducted before the step of applying the terminal layer structure, and the step of patterning the semiconductor layer sequence by means of the mask layer is conducted after the step of applying the terminal layer structure. In the final laser diode component, a part of the mask layer assigned to one semiconductor layer stack may form the insulating layer as mentioned above and thus may correspond to the insulating layer especially with respect to its structure and material composition.

The terminal layer structure is provided for producing a terminal layer of at least one laser diode component and thus may correspond to the terminal layer especially with respect to its layer structure and/or material composition as mentioned above.

According to at least one embodiment or configuration, in a first subsequent patterning step following the patterning of the second semiconductor layer and the active layer, the first semiconductor layer is patterned in such a way that an upper region and a lower region are produced, wherein the lower region is closer to the growth substrate than to the active layer and laterally projects beyond the upper region, which is closer to the active layer than to the growth substrate. Especially, the upper region is formed with a cut-off corner. The sacrificial layer may terminate the lower region on a side facing the growth substrate.

According to at least one embodiment or configuration, in a second subsequent patterning step, the lower region is patterned in such a way that it does not project laterally beyond the upper region any more except at the cut-off corner. At the cut-off corner, the sacrificial layer is accessible. Moreover, the lower region is patterned in such a way that the growth substrate projects laterally beyond the lower region in a laterally projecting area.

According to at least one embodiment or configuration, the step of applying the contact layer structure is conducted after the second subsequent patterning step. The contact layer structure may correspond to the first and second contact layers especially with respect to its layer structure and/or material composition as mentioned above. Advantageously, the first and second contact layers may be produced in one common step by providing the contact layer structure.

According to at least one embodiment or configuration, the step of providing the first dielectric layer structure follows the step of applying the contact layer structure. The first dielectric layer structure may correspond to the dielectric layer especially with respect to its layer structure and/or material composition as mentioned above.

For example, the first dielectric layer structure may be provided in such a way that it covers the laterally projecting area of the growth substrate. Moreover, the first dielectric layer structure may be provided in such a way that it extends from the growth substrate over outer surfaces of the semiconductor layer sequence to the contact layer structure on the second semiconductor layer.

For example, the first dielectric layer structure is provided with an aperture at the cut-off corner of the upper region, and the highly doped sacrificial layer is removed by an etchant introduced via the at least one aperture. The inventors have found that introducing the etchant from a corner rather than from all sides improves the removal of the sacrificial layer.

Advantageously, the first dielectric layer structure forms a tether structure in the laterally projecting area of the growth substrate, which tether structure holds the detached part of the semiconductor layer sequence to the growth substrate after removal of the sacrificial layer.

According to at least one embodiment or configuration, the first dielectric layer structure is provided with a first recess in an area of the contact layer structure provided for a first contact layer and with a second recess in an area of the contact layer structure provided for a second contact layer.

According to at least one embodiment or configuration, the step of applying the contact post structure follows the step of applying the first dielectric layer structure. The at least one first contact post and the at least one second contact post may be produced in one common step from the contact post structure.

The step of applying the contact post structure may involve the deposition of a seed layer, the electrodeposition of a metal layer, for example of an Ni layer, and the deposition of contact areas, for example made of Au. A photomask may be applied before the deposition of the seed layer and removed after the deposition of the contact areas, wherein the photomask provides the intended shapes to the at least one first contact post and the at least one second contact post.

According to at least one embodiment or configuration, the step of the removal of the sacrificial layer is conducted after the step of applying the contact post structure. The removal can involve an electrochemical etching process.

According to at least one embodiment or configuration, the step of removal of the sacrificial layer is followed by a step of applying a carrier structure on a side of the semiconductor layer sequence facing away from the growth substrate. The carrier structure is provided for producing at least one carrier and thus may correspond to the carrier especially with respect to its structure and/or material composition as mentioned above. Hence, the carrier structure may comprise a carrier substrate structure which results in at least one carrier substrate, and first connection means and second connection means structures which result in first connection means and second connection means.

The carrier structure may be bonded to the semiconductor layer sequence by thermo-compression or solder in a wafer-to-wafer bonding process, wherein the first connection means structure is connected to a first contact means structure including the at least one first part of the contact post structure and the second connection means structure is connected to a second contact means structure including the at least one second part of the contact post structure.

According to at least one embodiment or configuration, after the step of applying the carrier structure, the growth substrate is removed by detaching, for example breaking, the tether structure.

According to at least one embodiment or configuration, after the step of removing the growth substrate, a second dielectric layer structure is applied on a side of the semiconductor layer sequence facing away from the carrier structure in order to produce a second part of the at least one dielectric layer. The second dielectric layer structure may correspond to the dielectric layer especially with respect to its layer structure and/or material composition as mentioned above.

The production process allows for the production of a plurality of laser diode components in an assembly, wherein the laser diode components are singulated from the assembly at a finished stage. The production in the assembly allows to produce the laser diode components at lower costs.

The laser diode component is suitable as a light source in laser-based imagers for AR (augmented reality) and VR (virtual reality) applications.

Further preferred embodiments and further developments of the laser diode component and the manufacturing method for producing the laser diode component will become apparent from the exemplary embodiments explained below in conjunction with the figures.

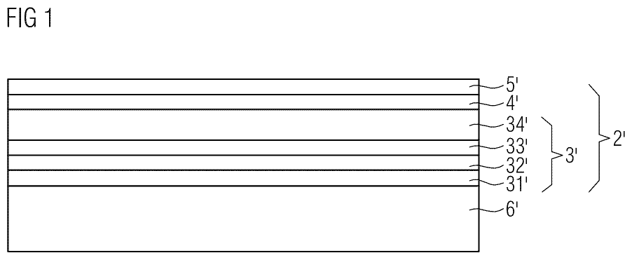

FIGS. 1 to 14 show schematic cross-sectional and plan views of method steps of exemplary embodiments of a manufacturing method for producing a laser diode component,

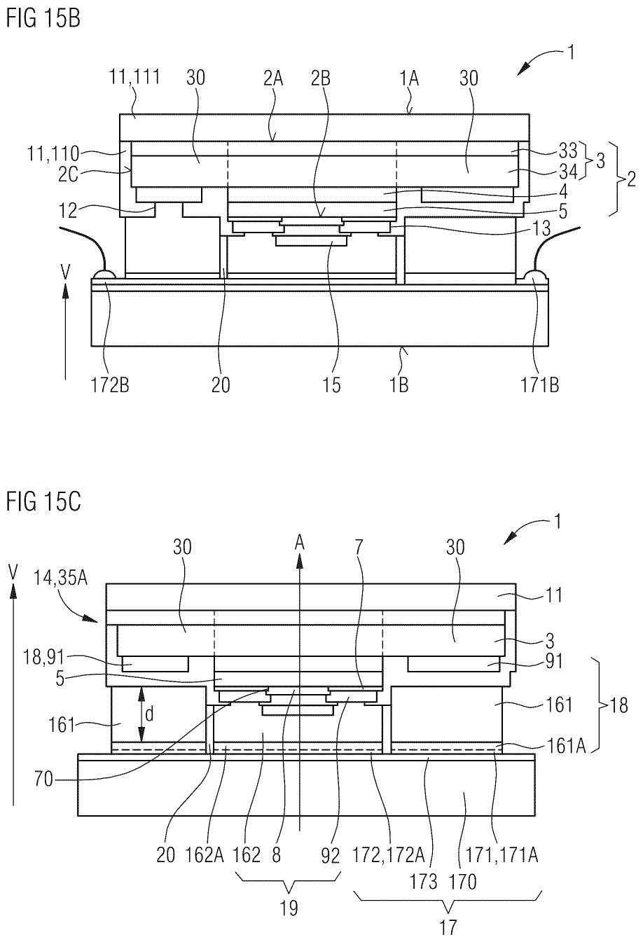

FIGS. 15A-15C, 16A-16B and 17A-17B show schematic cross-sectional and plan views of exemplary embodiments of a laser diode component.

Identical, equivalent or equivalently acting elements may be indicated with the same or similar reference numerals in the figures. The figures are schematic illustrations and thus not necessarily true to scale. Comparatively small elements and particularly layer thicknesses can rather be illustrated exaggeratedly large for the purpose of better clarification.

According to an exemplary embodiment of a method for producing a laser diode component, the method comprises providing a semiconductor layer sequence 2′ (see FIG. 1) for producing at least one semiconductor layer stack 2 (see FIGS. 15B, 16B, 17B). The semiconductor layer sequence 2′ comprises a first semiconductor layer 3′, a second semiconductor layer 5′ and an active layer 4′ for emitting laser radiation, wherein the active layer 4′ is arranged between the first semiconductor layer 3′ and the second semiconductor layer 5′.

The semiconductor layer sequence 2′ is provided on a growth substrate 6′, which may comprise or consist of a semiconductor material like GaN, for example. The first semiconductor layer 3′ faces the growth substrate 6′, whereas the second semiconductor layer 5′ faces away from the growth substrate 6′.

Materials based on arsenide, phosphide or nitride compound semiconductors are suitable for the semiconductor layers 3′, 4′, 5′ of the semiconductor layer sequence 2′. The meaning of “based on arsenide, phosphide or nitride compound semiconductors” has been explained above and is further relied on.

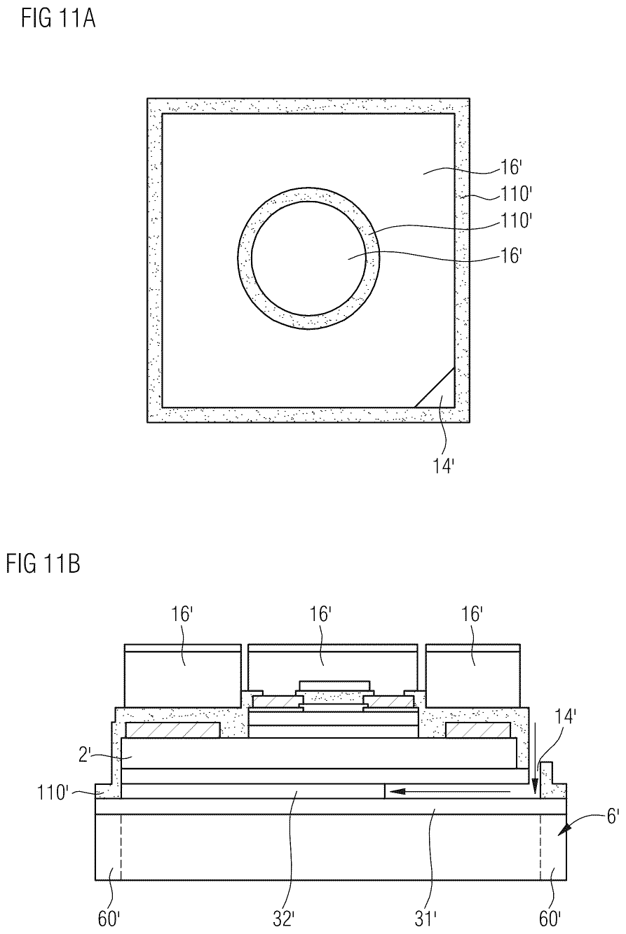

The first semiconductor layer 3′ is provided for producing a first semiconductor region 3 of at least one semiconductor layer stack 2 (see FIGS. 15B, 16B, 17B) and thus may correspond to the first semiconductor region 3 at least partly with respect to its layer structure and/or with respect to its material composition as mentioned above. The first semiconductor layer 3′ is of a first conductivity type, which may be an n-conductivity type, and has a multilayer structure. From the side facing the growth substrate 6′ to the side facing the active layer 4′, the first semiconductor layer 3′ comprises in the cited order an n-doped current spreading layer 31′, a highly n-doped sacrificial layer 32′, an unintentionally doped layer 33′ and an n-doped layer 34′. For example, all layers 31′, 32′, 33′ and 34′ are GaN layers. Moreover, the unintentionally doped layer 33′ has a lower doping concentration than the sacrificial layer 32′, which provides for a well-defined etch stop and smooth surface when detaching the semiconductor layer sequence 2′ from the growth substrate 6′ by electrochemically etching the sacrificial layer 32′ (see FIG. 11B). The sacrificial layer 32′ may have a doping concentration of 2×10¹⁸ to 10²⁰ cm⁻³, especially 8×10¹⁸ to 2×10¹⁹ cm⁻³. The n-dopant may be Si. The n-doped current spreading layer 31′ may have a doping concentration around 3×10¹⁸ cm⁻³.

The active layer 4′, which is provided for producing an active region 4 of at least one semiconductor layer stack 2 (see FIGS. 15B, 16B, 17B), may correspond to the active region 4 especially with respect to its layer structure and/or material composition as mentioned above and may comprise a sequence of single layers which form a quantum well structure, in particular a single quantum well (SQW) structure or multiple quantum well (MQW) structure.

The second semiconductor layer 5′ is provided for producing a second semiconductor region 5 of at least one semiconductor layer stack 2 (see FIGS. 15B, 16B, 17B) and thus may correspond to the second semiconductor region 5 especially with respect to its layer structure and/or material composition as mentioned above. The second semiconductor layer 5′ is of a second conductivity type, which may be a p-conductivity type, and has a single layer or multilayer structure. The second semiconductor layer 5′ may be a GaN layer.

The layers 3′, 4′, 5′ may be epitaxially deposited on the growth substrate 6′.

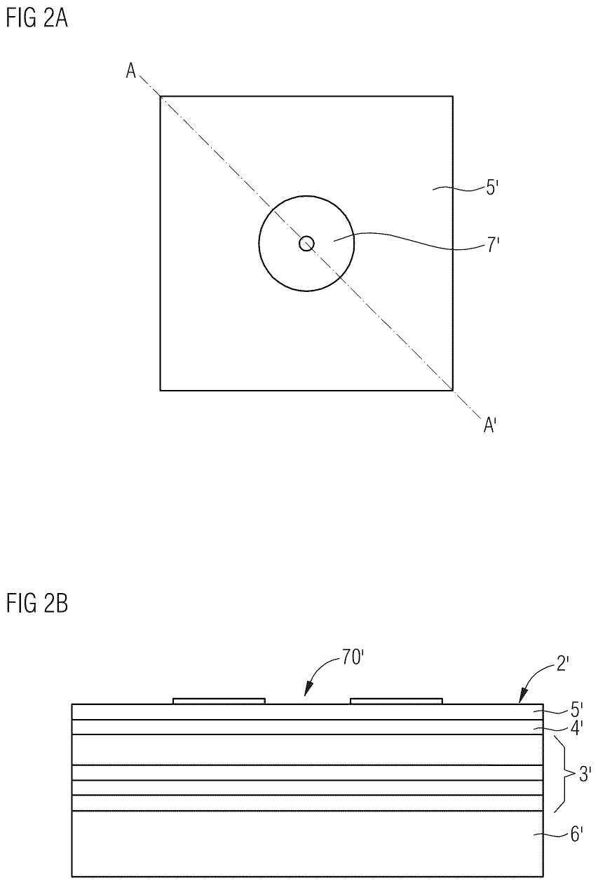

As illustrated in the schematic plan view of FIG. 2A and the schematic cross-sectional view of FIG. 2B taken along line AA′ shown in FIG. 2A, the step of providing the semiconductor layer sequence 2′ may be followed by applying a mask layer 7′ on parts of the second semiconductor layer 5′. The mask layer 7′ may have a rotationally symmetrical shape, especially a circular ring shape in the area of every semiconductor layer stack to be produced and may be provided with an opening 70′ in the area of every semiconductor layer stack to be produced. The mask layer 7′ may comprise an electrically insulating, transparent material like SiO2. The mask layer 7′ may be produced by evaporation. A part of the mask layer 7′ may remain in the final laser diode component 1 (see FIGS. 15B, 16B, 17B) and form an insulating layer 7 and thus may correspond to the insulating layer especially with respect to its structure and material composition.

The step of applying the mask layer 7′ may be preceded by a passivation step of an outer surface of the second semiconductor layer 5′, which may be conducted by dry etching, for example by reactive-ion etching.

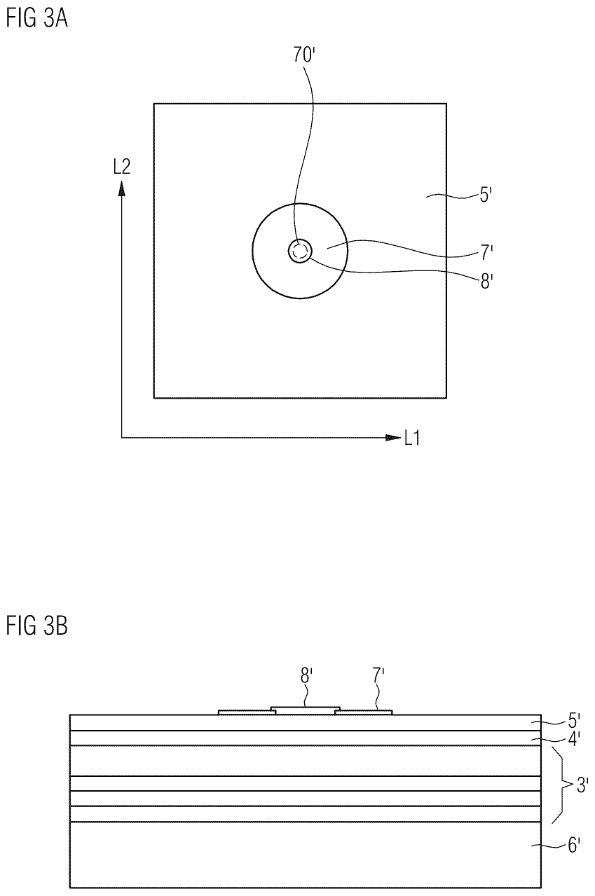

As illustrated in the schematic plan view of FIG. 3A and the schematic cross-sectional view of FIG. 3B taken along the same line AA′ as shown in FIG. 2A, the step of applying the mask layer 7′ is followed by a step of applying a terminal layer structure 8′ on parts of the second semiconductor layer 5′ for producing at least one terminal layer 8 (see FIGS. 15B, 16B, 17B). For example, the terminal layer structure 8′ is applied in such a way that it fills the opening(s) 70′ of the mask layer 7′ and covers an edge of an outer surface of the mask layer 7′ facing away from the second semiconductor layer 5′, wherein the edge laterally surrounds the opening(s) 70′. “Laterally” or “lateral” means in one or more lateral directions, wherein the one or more lateral directions are parallel to a main extension plane of the semiconductor layer sequence 2′ or semiconductor layer stack. A first lateral direction L1 and a second lateral direction L2 are shown in FIG. 3A.

The terminal layer structure 8′ has a rotationally symmetrical shape, especially a circular shape in the area of every semiconductor layer stack to be produced. The terminal layer structure 8′ may be formed from a transparent, electrically conductive material like a TOO (Transparent Conductive Oxide) and/or include a semiconductor tunnel junction. The terminal layer structure 8′ is provided for producing a terminal layer 8 of at least one semiconductor layer stack 2 and thus may correspond to the terminal layer especially with respect to its layer structure and/or material composition (see FIGS. 15B, 16B, 17B).

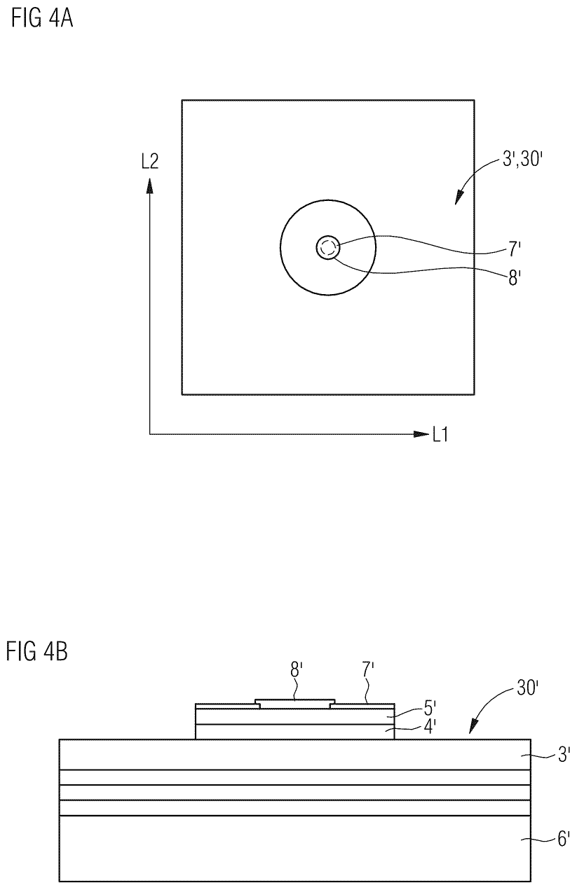

As illustrated in the schematic plan view of FIG. 4A and the schematic cross-sectional view of FIG. 4B taken along the same line AA′ as shown in FIG. 2A, the step of applying the terminal layer structure 8′ is followed by a step of patterning the semiconductor layer sequence 2′ by means of the mask layer 7′ in such a way that the first semiconductor layer 3′ has a projecting area 30′ in the area of every semiconductor layer stack to be produced, wherein the first semiconductor layer 3′ laterally projects beyond the active layer 4′ and the second semiconductor layer 5′ in the projecting area 30′. The patterning may be conducted by dry etching, for example by reactive-ion etching.

Especially, the second semiconductor layer 5′ and the active layer 4′ do not laterally project beyond the mask layer 7′ in the area of the same semiconductor layer stack to be produced. Lateral extensions may be equal to the lateral extensions of the corresponding part of the mask layer 7′. Moreover, a shape of the second semiconductor layer 5′ and the active layer 4′ may be determined by the mask layer 7′. Hence, the second semiconductor layer 5′ and the active layer 4′ may have a circular side edge.

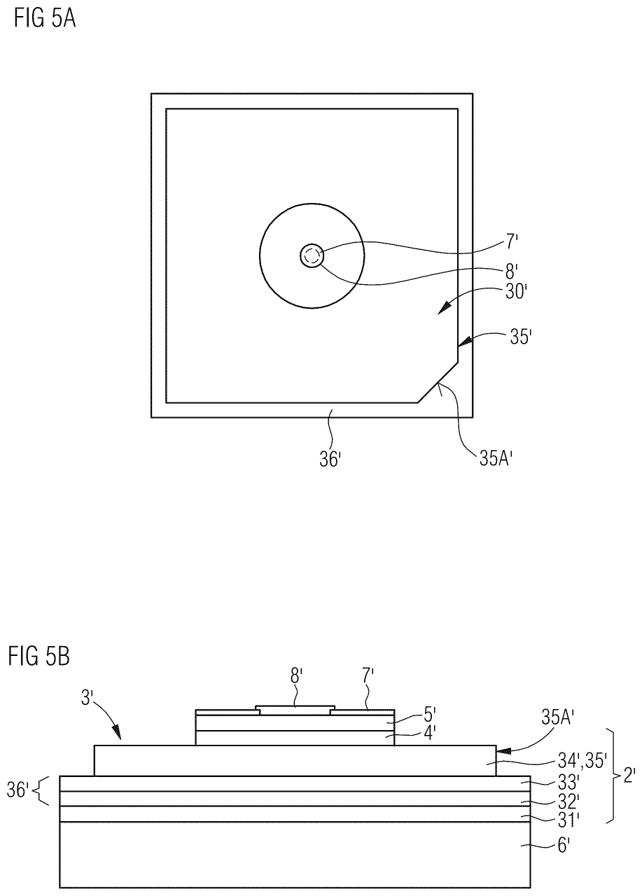

As illustrated in the schematic plan view of FIG. 5A and the schematic cross-sectional view of FIG. 5B taken along the same line AA′ as shown in FIG. 2A, the step of patterning the semiconductor layer sequence 2′ in the area of the second semiconductor layer 5′ and active layer 4′ is followed by a first subsequent patterning step, wherein the first semiconductor layer 3′ is patterned in such a way that an upper region 35′ and a lower region 36′ are produced, wherein the lower region 36′ is closer to the growth substrate 6′ than to the active layer 4′ and laterally projects beyond the upper region 35′, which is closer to the active layer 4′ than to the growth substrate 6′. Especially, the upper region 35′ is formed with a cut-off corner 35A′. The upper region 35′ may comprise the n-doped layer 34′, while the lower region 36′ may comprise the highly n-doped sacrificial layer 32′ and the unintentionally doped layer 33′, wherein the sacrificial layer 32′ terminates the lower region 36′ on a side facing the growth substrate 6′. The patterning of the first subsequent patterning step may be conducted by dry etching, for example by reactive-ion etching.

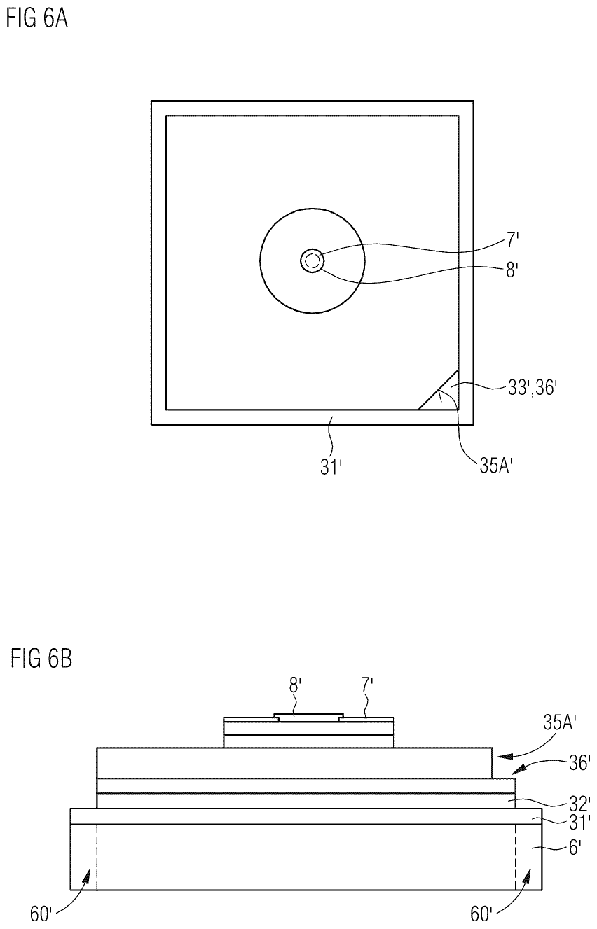

As illustrated in the schematic plan view of FIG. 6A and the schematic cross-sectional view of FIG. 6B taken along the same line AA′ as shown in FIG. 2A, the first subsequent patterning step is followed by a second subsequent patterning step, wherein the lower region 36′ is patterned in such a way that it does not project laterally beyond the upper region 35′ any more except at the cut-off corner 35A′. At the cut off corner 35A′, the sacrificial layer 32′ is accessible. Moreover, the lower region 36′ is patterned in such a way that the growth substrate 6′ projects laterally beyond the lower region 36′ in a laterally projecting area 60′. The patterning of the second subsequent patterning step may be conducted by dry etching, for example by reactive-ion etching.

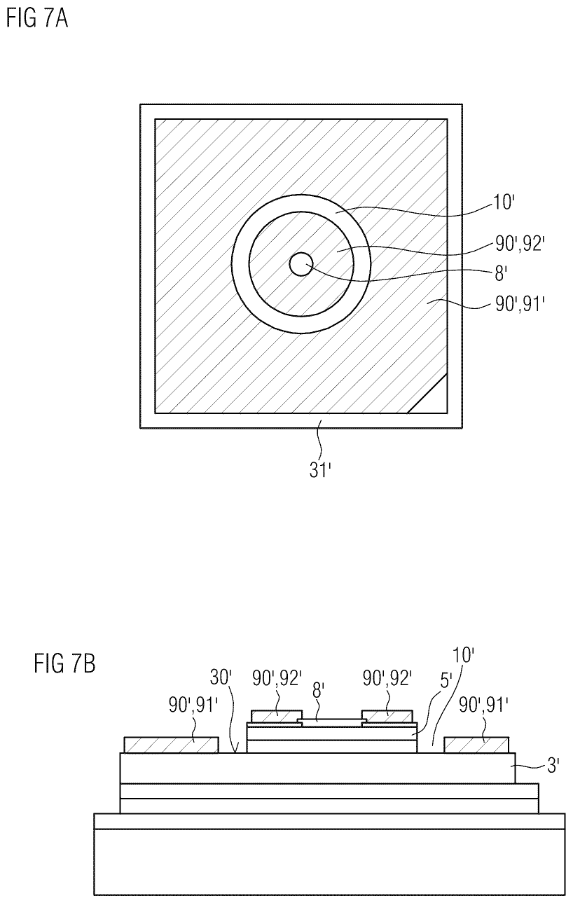

As illustrated in the schematic plan view of FIG. 7A and the schematic cross-sectional view of FIG. 7B taken along the same line AA′ as shown in FIG. 2A, the second subsequent patterning step is followed by applying a contact layer structure 90′ for producing at least one first contact layer 91 and at least one second contact layer 92 (see FIGS. 15B, 16B, 17B), wherein the contact layer structure 90′ is applied on the projecting area(s) 30′ of the first semiconductor layer 3′ and on the second semiconductor layer 5′ in such a way that the contact layer structure 90′ laterally surrounds the terminal layer structure 8′ in the area of every semiconductor layer stack to be produced.

Especially, a first part 91′ of the contact layer structure 90′ in the area of every semiconductor layer stack to be produced and supposed to constitute a first contact layer 91 in the final laser diode component laterally surrounds a second part 92′ of the contact layer structure 90′, which is arranged in the area of every semiconductor layer stack to be produced and is supposed to constitute a second contact layer 92 in the final laser diode component. The second part 92′ laterally surrounds and partly laterally overlaps with a part of the terminal layer structure 8′ in the area of every semiconductor layer stack to be produced. The first part 91′ and the second part 92′ are spaced apart by a ring-shaped interspace 10′.

The contact layer structure 90′ may be a metallic layer formed from a metal or metal composition. The contact layer structure 90′ may correspond to the first and second contact layers 91, 92 especially with respect to its layer structure and/or material composition. Advantageously, the first and second contact layers 91, 92 may be produced in one common step by providing the contact layer structure 90′.

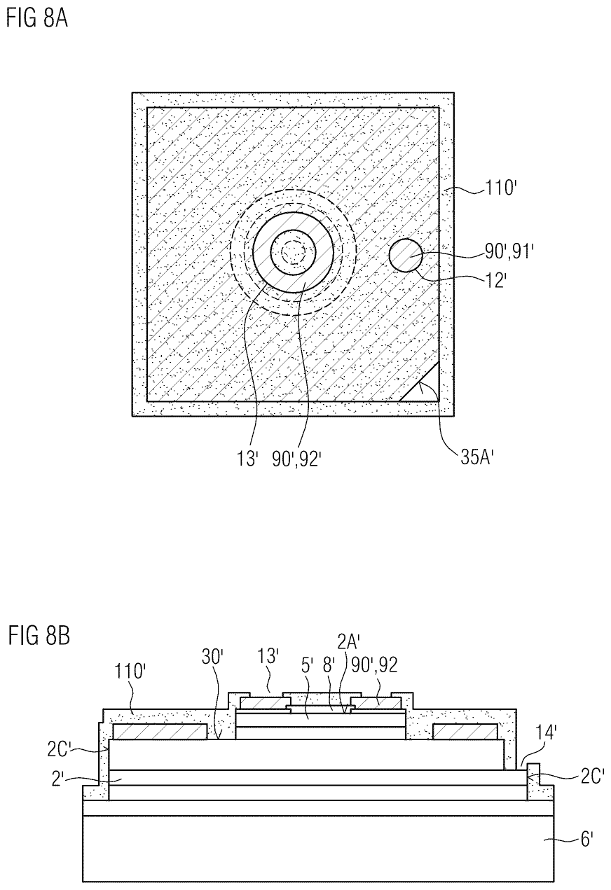

As illustrated in the schematic plan view of FIG. 8A and the schematic cross-sectional view of FIG. 8B taken along the same line AA′ as shown in FIG. 2A, the step of applying the contact layer structure 90′ is followed by applying a first dielectric layer structure 110′ on the semiconductor layer sequence 2′ in order to produce a first part 110 of at least one dielectric layer 11 (see FIGS. 15B, 16B, 17B).

The first dielectric layer structure 110′ may correspond to the first part 110 of the dielectric layer 11 or dielectric layer 11 especially with respect to its layer structure and/or material composition as mentioned above. The first dielectric layer structure 110′ may be a multilayer structure comprising at least two sublayers of different dielectric materials having different refractive indices. Suitable materials for the first dielectric layer structure 110′ or the sublayers are dielectric materials like titanium oxide and silicon dioxide.

The first dielectric layer structure 110′ is provided in such a way that it extends from the growth substrate 6′ over outer surfaces 2A′, 2C′ of the semiconductor layer sequence 2′ to the contact layer structure 90′, 92′ on the second semiconductor layer 5′. While the contact layer structure 90′, 92′ on the second semiconductor layer 5′ is covered only partially, the terminal layer structure 8′ is wholly covered by the first dielectric layer structure 110′.

The first dielectric layer structure 110′ is provided with a first recess 12′ in the area of the first part 91′ of the contact layer structure 90′ provided for a first contact layer and with a second recess 13′ in the area of the second part 92′ of the contact layer structure 90′ provided for a second contact layer. While the second recess 13′ has the same shape as the second part 92′, which may be ring-shaped, the first recess 12′ differs from the shape of the first part 91′ and has a circular shape. However, it might also be vice versa, i.e. that the second recess 13′ has a circular shape, while the first recess 12′ is ring-shaped.

Moreover, the first dielectric layer structure 110′ is provided with an aperture 14′ at the cut-off corner 35A′ of the upper region 35′ in the area of every semiconductor layer stack to be produced.

The production of the first dielectric layer structure 110′ having the recesses 12′, 13′ and aperture(s) 14′ may involve a photolithography process.

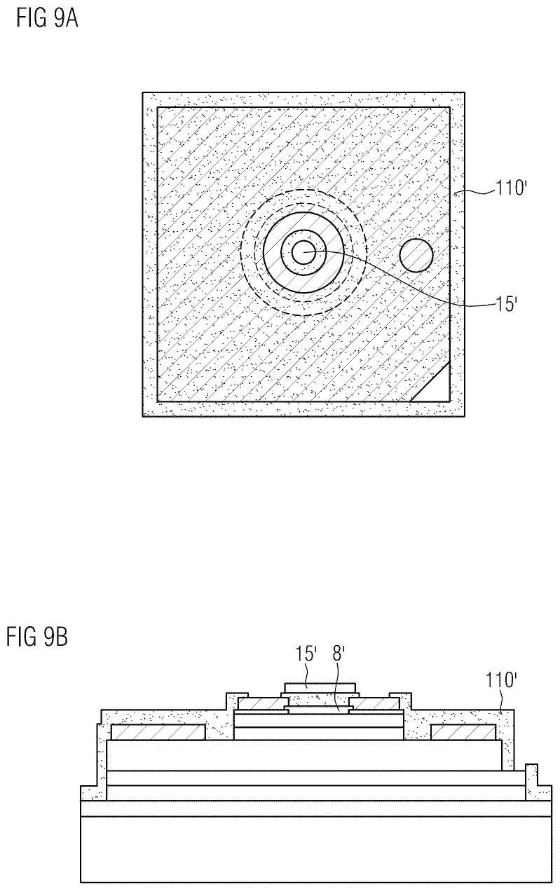

As illustrated in the schematic plan view of FIG. 9A and the schematic cross-sectional view of FIG. 9B taken along the same line AA′ as shown in FIG. 2A, the step of applying the first dielectric layer structure 110′ may be followed by an optional step of applying a mirror layer structure 15′ on the first dielectric layer structure 110′ on a side of the first dielectric layer structure 110′ facing away from the terminal layer structure 8′. The mirror layer structure 15′ may be provided for at least one mirror layer 15 (see FIGS. 15B, 16B, 17B) and may be a metallic layer structure, which contains Al or Ag, for example.

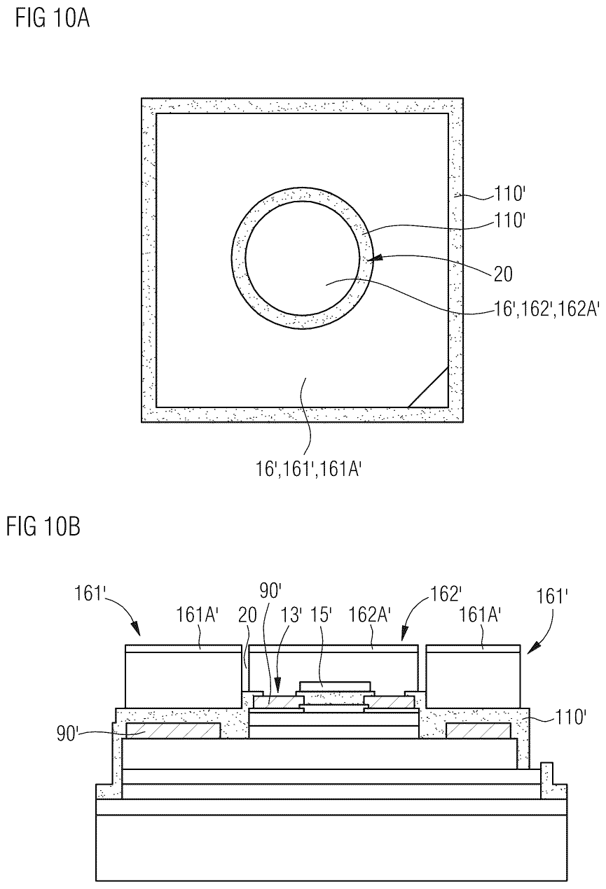

As illustrated in the schematic plan view of FIG. 10A and the schematic cross-sectional view of FIG. 10B taken along the same line AA′ as shown in FIG. 2A, the step of applying the first dielectric layer structure 110′ or the optional step of applying a mirror layer structure 15′ is followed by applying a contact post structure 16′ on the first dielectric layer structure 110′ in such a way that a first contact area 161A′ of at least one first part 161′ of the contact post structure 16′ provided for producing at least one first contact post 161 laterally surrounds a second contact area 162A′ of at least one second part 162′ of the contact post structure 16′ provided for producing at least one second contact post 162 (see FIGS. 15B, 16B, 17B). The contact post structure 16′ extends into the first and second recesses 12′, 13′ and contacts the contact layer structure 90′ there.

The step of applying the contact post structure 16′ may involve the deposition of a seed layer, the electrodeposition of a metal layer, for example of an Ni layer, and the deposition of a contact area layer, for example made of Au, wherein the first and second contact areas 161A′, 162A′ are produced from the same contact area layer. A photomask may be applied before the deposition of the seed layer and removed after the deposition of the contact area layer, wherein the photomask provides the intended shape to the contact post structure 16′.

As illustrated in the schematic plan view of FIG. 11A and the schematic cross-sectional view of FIG. 11B taken along the same line AA′ as shown in FIG. 2A, the step of applying the contact post structure 16′ is followed by removing the highly doped sacrificial layer 32′ by an etchant (see arrows) introduced via the at least one aperture 14′. The inventors have found that introducing the etchant from a corner rather than from all sides improves the removal of the sacrificial layer 32′.

The removal can involve an electrochemical etching process. The electrochemical etching process involves placing the assembly in an acid and applying an etching voltage. The etching rate can be adjusted by the etching voltage and/or the doping concentration of the sacrificial layer 32′. For example, the etching rate may be increased by increasing the etching voltage and/or the doping concentration of the sacrificial layer 32′.

Advantageously, the first dielectric layer structure 110′ forms a tether structure in the laterally projecting area 60′ of the growth substrate 6′, which tether structure holds the detached part of the semiconductor layer sequence 2′ to the growth substrate 6′ after removal of the sacrificial layer 32′. For example, the n-doped current spreading layer 31′ may remain on the growth substrate 6′.

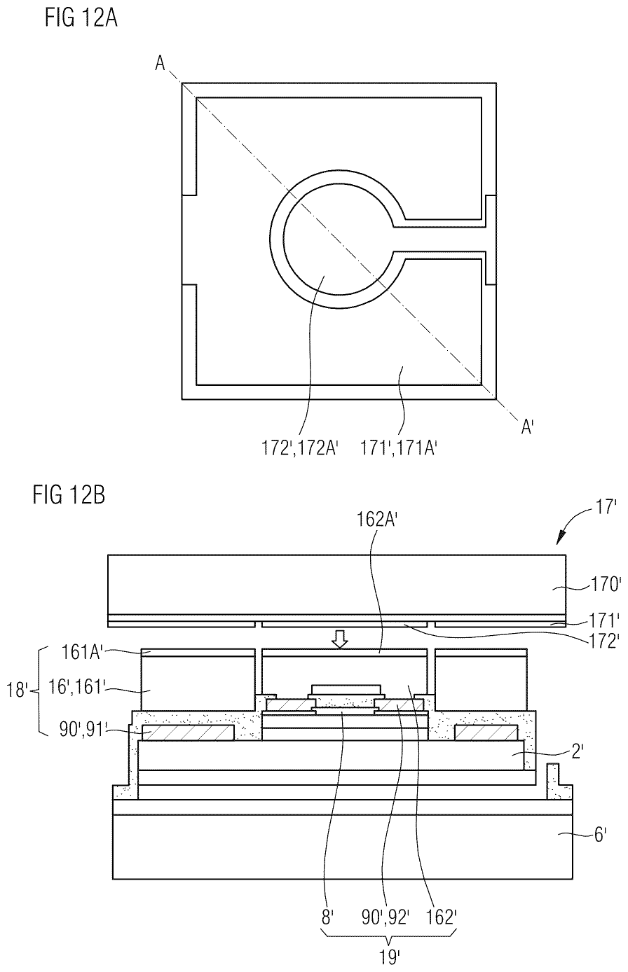

As illustrated in the schematic plan view of FIG. 12A and the schematic cross-sectional view of FIG. 12B taken along the same line AA′ as shown in FIG. 2A, the step of the removal of the sacrificial layer 32′ is followed by a step of applying a carrier structure 17′ on a side of the semiconductor layer sequence 2′ facing away from the growth substrate 6′. The carrier structure 17′ is provided for producing at least one carrier 17 (see FIGS. 15B, 16B, 17B) and thus may correspond to the carrier 17 especially with respect to its structure and/or material composition. The carrier structure 17′ may comprise a carrier substrate structure 170′ which results in at least one carrier substrate 170 and may comprise first connection means and second connection means structures 171′, 172′ which result in first connection means 171 and second connection means 172 for at least one laser diode component 1 (see FIGS. 15B, 16B, 17B).

The carrier structure 17′ is bonded to the semiconductor layer sequence 2′, for example by thermo-compression or soldering in a wafer-to-wafer bonding process, wherein the first connection means structure 171′ is connected to a first contact means structure 18′ including the at least one first part 91′ of the contact layer structure 90′ and the at least one first part 161′ of the contact post structure 16′. Moreover, the second connection means structure 172′ is connected to a second contact means structure 19′ including the terminal layer structure 8′, the at least one second part 92′ of the contact layer structure 90′ and the at least one second part 162′ of the contact post structure 16′.

The first connection means structure 171′ comprises a first connection area 171A′ in the area of a carrier 17 to be produced and comprises a second connection area 172A′ in the area of the carrier 17 to be produced. As shown in FIG. 12A, the first connection area 171A′ may partly laterally surround the second connection area 172A′, wherein a part of the second connection area 172A′ extends through the first connection area 171A′ to an edge of the carrier 17 to be produced. Especially, the shape of the first connection area 171A′ essentially matches the shape of the first contact area 161A′, and the shape of the second connection area 172A′ essentially matches the shape of the second contact area 162A′.

The carrier substrate structure 170′ may be formed from a material matching the coefficient of thermal expansion of the material of the semiconductor layer sequence 2′ like for example silicon, ceramics or suitable metal materials.

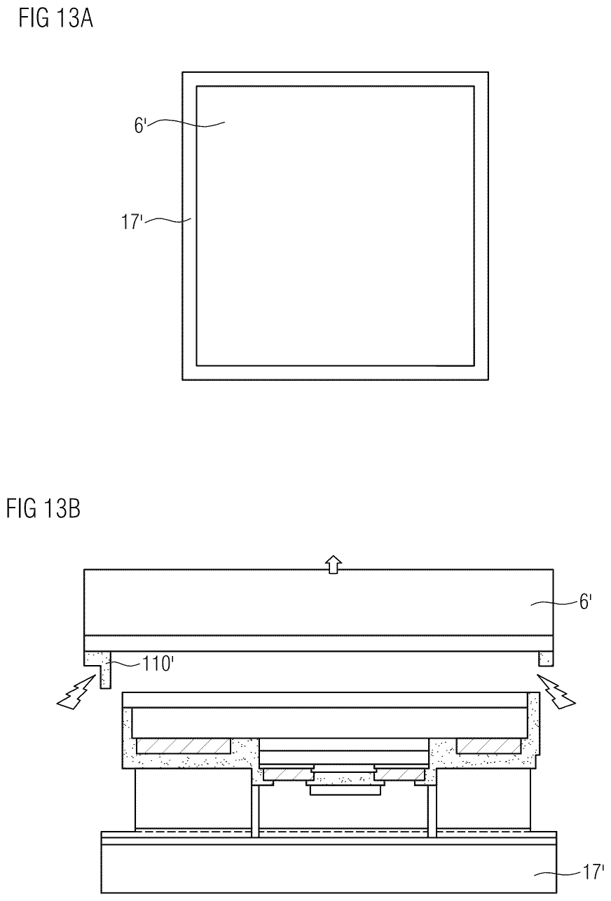

As illustrated in the schematic plan view of FIG. 13A and the schematic cross-sectional view of FIG. 13B taken along the same line AA′ as shown in FIG. 2A, after the step of applying the carrier structure 17′, the growth substrate 6′ is removed by detaching (see arrows), for example breaking, the tether structure of the first dielectric layer structure 110′.

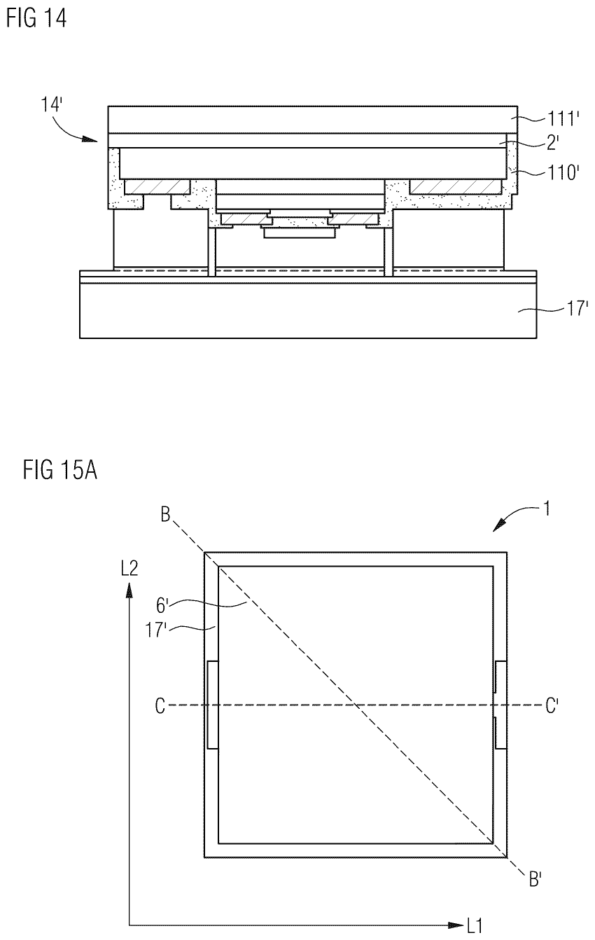

As illustrated in the cross-sectional view of FIG. 14 taken along the same line AA′ as shown in FIG. 2A, the step of removing the growth substrate 6′ is followed by applying a second dielectric layer structure 111′ on a side of the semiconductor layer sequence 2′ facing away from the carrier structure 17′ in order to produce a second part 111 of at least one dielectric layer 11 (see FIGS. 15B, 16B, 17B). The second dielectric layer structure 111′ may correspond to the dielectric layer 11 especially with respect to its layer structure and/or material composition.

The step of applying a second dielectric layer structure 111′ may be followed by a singulation process, wherein a plurality of laser diode components 1 as shown in FIGS. 15A to 15C may be separated from the assembly at a finished stage. The production in the assembly allows to produce the laser diode components 1 at lower costs.

In connection with the schematic plan view of FIG. 15A, the schematic cross-sectional view of FIG. 15B taken along line BB′ as shown in FIG. 15A and the schematic cross-sectional view of FIG. 15C taken along line CC′ as shown in FIG. 15A, an exemplary embodiment of a laser diode component 1 is described, which can be produced by the method described in connection with FIGS. 1 to 14.

The laser diode component 1 is a thinfilm VCSEL and has a flip-chip design.

The laser diode component 1 comprises a semiconductor layer stack 2 formed from the semiconductor layer sequence 2′ (see FIG. 1), wherein the semiconductor layer stack 2 includes a first semiconductor region 3 of a first conductivity type, for example an n-doped semiconductor region, includes a second semiconductor region 5 of a second conductivity type, for example a p-doped semiconductor region, and includes an active region 4 for emitting laser radiation, wherein the active region 4 is arranged between the first semiconductor region 3 and the second semiconductor region 5 and may comprise a quantum well structure as mentioned above. The first semiconductor region 3 may comprise several layers like an unintentionally doped layer 33 formed from the unintentionally doped layer 33′ and an n-doped layer 34 formed from the n-doped layer 34′ (see FIG. 1). The second semiconductor region 5 may also have a multilayer structure.

Materials as discussed above based on arsenide, phosphide or nitride compound semiconductors, for example, are suitable for the semiconductor regions 3, 4, 5 or single layers of the semiconductor layer stack 2.

The first semiconductor region 3 has a projecting area 30, where the first semiconductor region 3 laterally projects beyond the active region 4 and the second semiconductor region 5. “Laterally” means in one or more lateral directions like a first lateral direction L1 or second lateral direction L2, wherein the one or more lateral directions are parallel to a main extension plane of the semiconductor layer stack 2. For example, the second semiconductor region 5 and the active region 4 have a circular side edge, whereas the first semiconductor region 3 has a rectangular side edge.

The laser diode component 1 comprises a dielectric layer 11 covering the semiconductor layer stack 2. The dielectric layer 11 is arranged on opposite surfaces of the semiconductor layer stack 2 and sandwiches the active region 4. The dielectric layer 11 comprises a first part 110 resulting from the first dielectric layer structure 110′ (see FIGS. 8A and 8B) and covering the semiconductor layer stack 2 on a second main surface 2B facing the carrier 17 as well as on side surfaces 2C laterally delimiting the semiconductor layer stack 2. The dielectric layer 11 comprises a second part 111 resulting from the second dielectric layer structure 111′ (see FIG. 14) and covering the semiconductor layer stack 2 on a first main surface 2A facing away from the carrier 17.

The dielectric layer 11 as well as its first and second parts 110, 111 may be a multilayer comprising at least two sublayers of different dielectric materials having different refractive indices. Suitable materials for the dielectric layer or the sublayers are dielectric materials like titanium oxide and silicon dioxide.

The dielectric layer 11 forms a laser resonator of the laser diode component 1. Especially, the first part 110 and the second part 111 arranged on opposite sides of the active region 4 are DBR (Distributed Bragg Reflector) mirrors, which constitute a vertical laser resonator, wherein the laser radiation is emitted in a vertical direction V and exits the laser diode component 1 on a radiation exit side, which is a front side 1A arranged at the side of the first main surface 2A. The vertical direction V may run perpendicular to the main extension plane. The dielectric layer 11 enables wide stopbands and higher reflectivities, for example above 99%, than semiconductor resonators.

Advantageously, removing the growth substrate 6′ (see FIGS. 13, 14) allows for forming the laser resonator exclusively from the dielectric layer 11. Moreover, by removing the growth substrate 6′, a thickness of the semiconductor layer stack 2 can be optimized to form an optical cavity between the first and second parts 110, 111. The laser diode component 1 where the growth substrate 6′ has been removed or at least thinned constitutes a thinfilm device.

The laser diode component 1 comprises first contact means 18 for electrically contacting the first semiconductor region 3 and second contact means 19 for electrically contacting the second semiconductor region 5 (see FIG. 15C).

The first contact means 18 comprises a first contact layer 91, which covers the projecting area 30 of the first semiconductor region 3. The first contact layer 91 is formed from the contact layer structure 90′ (see FIGS. 7A, 7B) and may be a metallic layer formed from a metal or metal composition.

The first contact means 18 further comprises a first contact post 161, which is arranged on a side of the first contact layer 91 facing away from the first semiconductor region 3. The first contact post 161 is formed from the contact post structure 16′ (see FIGS. 10, 10B) and may be a metallic multilayer formed from one or more metals or metal compositions. For example, the first contact post 161 comprises a metal layer made of Ni, for example, and a first contact area 161A containing Au, for example. The first contact post 161 may be thicker than the first contact layer 91. The metal layer of the first contact post 161 may have a thickness d between 5 and 100 μm, preferably between 10 and 50 μm, most preferably between 20 and 30 μm.

The second contact means 19 comprises a terminal layer 8, which partly covers the second semiconductor region 5 and is arranged in the vertical direction V between the dielectric layer 11 and the second semiconductor region 5. The terminal layer 8 has a rotationally symmetrical shape with respect to a centre axis A of the laser diode component 1, for example a circular or circular ring shape.

For example, the terminal layer 8 is formed from a TOO (Transparent Conductive Oxide) and/or includes a semiconductor tunnel junction. The terminal layer 8 is designed to have low optical absorption. Hence, the laser radiation emitted from the active zone 4 in the direction of the terminal layer 8 may pass the terminal layer 8 and may be reflected at the highly reflective dielectric layer 11.

The second contact means 19 comprises a second contact layer 92 laterally surrounding and partly laterally overlapping with the terminal layer 8 at the second semiconductor region and electrically contacting the terminal layer 8. The second contact layer 92 is formed from the contact layer structure 90′ (see FIGS. 7A, 7B) and may be a metallic layer formed from a metal or metal composition.

Moreover, the second contact means 19 comprises a second contact post 162, which is arranged on a side of the second contact layer 92 facing away from the second semiconductor region 5. The second contact post 162 is formed from the contact post structure 16′ (see FIGS. 10, 10B) and may be a metallic multilayer formed from one or more metals or metal compositions. For example, the second contact post 162 may comprise an Ni layer and a second contact area 162A containing Au, for example. The second contact post 162 may be thicker than the second contact layer 92.

The first contact post 161 laterally surrounds the second contact post 162. It is possible that the first contact post 161 does not completely laterally surround the second contact post 162. The first and second contact posts 161, 162 electrically contact the respective contact layers 91, 92 and are suitable for heat dissipation during operation.

The dielectric layer 11 comprises a first recess 12 and a second recess 13, and the first contact means 18 are, especially the first contact post 161 is, partly arranged in the first recess 12, and the second contact means 19 are, especially the second contact post 162 is, partly arranged in the second recess 13. Moreover, the dielectric layer comprises an aperture 14 at a side surface of the semiconductor layer stack 2. Especially, the aperture 14 is in the region of a cut-off corner 35A (see FIG. 15C) and results from the cut-off corner 35A′ mentioned in connection with FIG. 10A.

The first contact area 161A of the first contact post 161 laterally surrounds the second contact area 162A of the second contact post 162. The second contact area 162A has a rotationally symmetrical shape with respect to the centre axis A of the laser diode component 1. The second contact area 162A has a circular shape. Furthermore, the first contact area 161A has a circular inner edge facing the second contact area 162A and has an essentially rectangular outer edge facing away from the second contact area 162A, wherein a corner of the outer edge is cut off (see FIG. 10A and cut off corner 35A in FIG. 15C).

The rotationally symmetrical design of the contact areas assures superior robustness of the laser diode component 1.

The first contact post 161 and the second contact post 162 are spaced apart by a separation trench 20. For example, the separation trench 20 has a rotationally symmetrical shape with respect to the centre axis A of the laser diode component 1. The separation trench 20 may have the shape of a circular ring (see FIG. 10A). Advantageously, the rotationally symmetrical shape of the separation trench 20 helps to balance the thermomechanical stress and thus reduce the risk of damages.

The first contact area 161A and the second contact area 162A are arranged in a common contact plane, wherein the common contact plane is arranged on a side of the active region 4 opposite to the radiation exit side 1A of the laser diode component 1. Thus, the laser diode component 1 has a flip-chip design.

The laser diode component 1 comprises an insulating layer 7, wherein the insulating layer 7 partly covers the second semiconductor region 5 and comprises an opening 70, where the terminal layer 8 is arranged and contacts the second semiconductor region 5. The second semiconductor region 5 and the active region 4 do not laterally project beyond the insulating layer 7. Especially, a lateral extension and shape of the second semiconductor region 5 and the active region 4 is determined by the insulating layer 7.

In the vertical direction V, the insulating layer 7 is arranged between the second contact layer 92 and the second semiconductor region 5. The insulating layer 7 has the shape of a circular ring.

During operation, the insulating layer 7 may serve as a current confinement layer for laterally confining a current flow through the semiconductor layer stack 2. For example, the insulating layer 7 is formed from the mask layer 7′ (see FIG. 2B) and may comprise a transparent, electrically insulating material like SiO2.

Optionally, the laser diode component 1 comprises a mirror layer 15, which may be metallic and may contain Al or Ag, for example. The mirror layer 15 is arranged on a side of the dielectric layer 11 facing away from the terminal layer and laterally overlaps with the terminal layer 8. The reflectivity can be increased by the mirror layer 15.

The laser diode component 1 comprises a carrier 17 including first connection means 171 and second connection means 172, wherein a first connection area 171A of the first connection means 171 is connected to the first contact area 161A of the first contact means 18 and a second connection area 172A of the second connection means 172 is connected to the second contact area 162A of the second contact means 19.

The laser diode component 1 comprises a first device electrode 171B and a second device electrode 172B for electrically contacting the laser diode component 1 from outside, wherein the first device electrode 171B is a part of the first connection means 171 and the second device electrode 172B is a part of the second connection means 172.

The first connection area 171A partly laterally surrounds the second connection area 172A as described in connection with FIG. 12A. Especially, the shape of the first connection area 171A essentially matches the shape of the first contact area 161A except for the interruption in the area of a second device electrode 172B, which can be missing in the first contact area 161A (see FIG. 11A). Moreover, the shape of the second connection area 172A essentially matches the shape of the second contact area 162A.

The carrier 17 comprises a carrier substrate 170 formed from a material matching the coefficient of thermal expansion of the material of the semiconductor layer stack 2 like for example silicon, ceramics or suitable metal materials. The first connection area 171A and the second connection area 172A are arranged on a side of the carrier substrate 170 facing the semiconductor layer stack 2. An isolation layer 173 may be arranged between the carrier substrate 170 and the connection means 171, 172 in case the carrier substrate 170 is electrically conductive.

The semiconductor layer stack 2 is arranged on the carrier 17 in such a way that the second semiconductor region 5 faces the carrier 17. The carrier 17 is arranged at a rear side 1B of the laser diode component 1 facing away from the radiation exit side 1A. The device electrodes 171B, 172B are arranged at opposite side surfaces of the laser diode component 1.

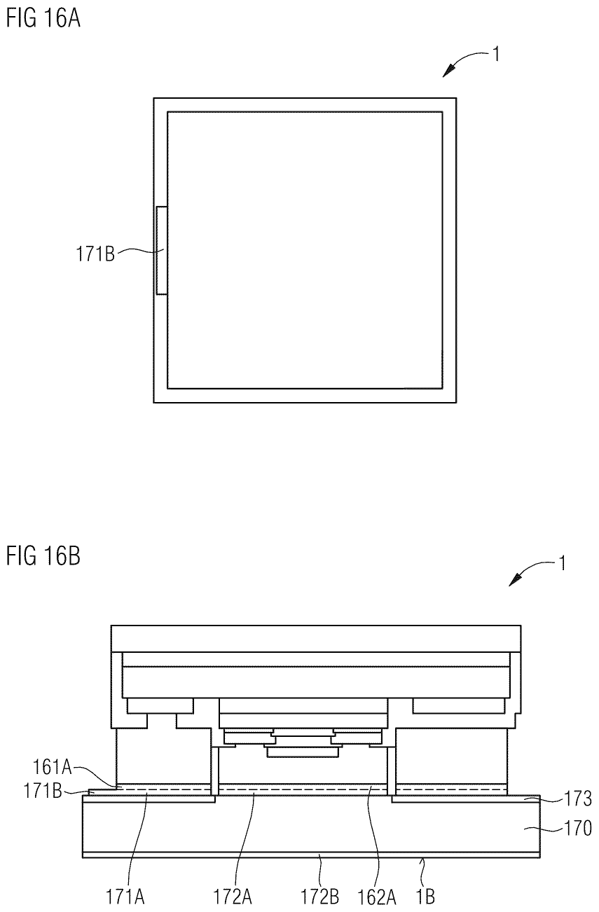

In connection with the schematic plan view of FIG. 16A and the schematic cross-sectional view of FIG. 16B taken along the same line CC′ as shown in FIG. 15A, another exemplary embodiment of a laser diode component 1 is described, which can be produced by the method described in connection with FIGS. 1 to 14.

The carrier 17 comprises an electrically conductive substrate 170, which provides for an electrical connection between the second connection area 172A and the second device electrode 172B, which is arranged on a side of the carrier substrate 170 facing away from the semiconductor layer stack 2. In this exemplary embodiment, the second contact area 162A and the second connection area 172A may have an identical circular shape. The first contact area 161A and the first connection area 171A may have an identical circular ring shape. The first device electrode 171B is arranged at a side surface of the laser diode component 1, while the second device electrode 172B is arranged at the rear side 1B.

In addition, the laser diode component 1 may have any of the features, characteristics and advantages mentioned in connection with the further exemplary embodiments.

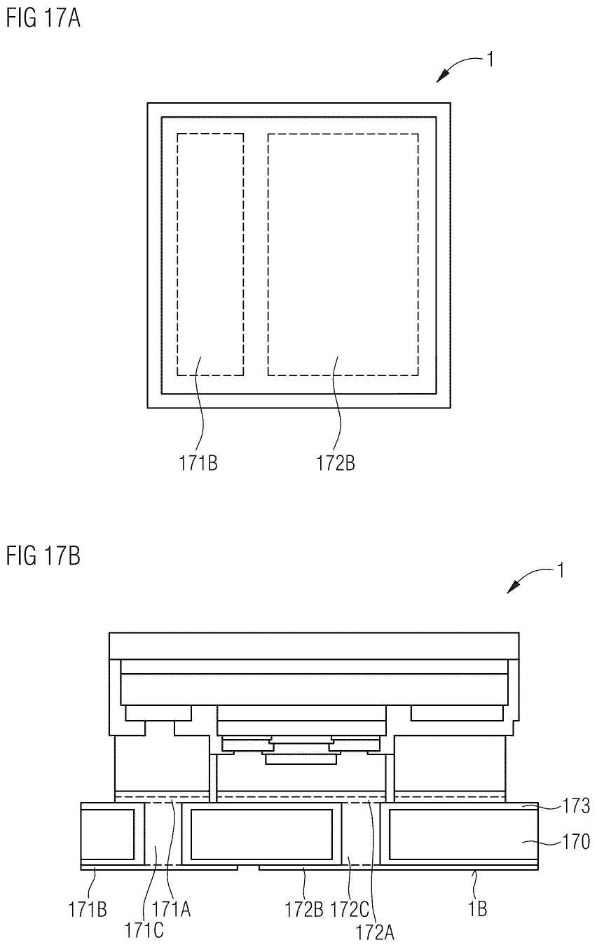

In connection with the schematic plan view of FIG. 17A and the schematic cross-sectional view of FIG. 17B taken along the same line CC′ as shown in FIG. 15A, another exemplary embodiment of a laser diode component 1 is described, which can be produced by the method described in connection with FIGS. 1 to 14.

The first connection means 171 comprises a first electrically conductive via 171C, which leads trough the carrier substrate 170 and provides for an electrical connection between the first connection area 171A and the first device electrode 171B, which is arranged on a side of the carrier substrate 170 facing away from the semiconductor layer stack 2. Moreover, the second connection means 172 comprise a second electrically conductive via 172C, which leads trough the carrier substrate 170 and provides for an electrical connection between the second connection area 172A and the second device electrode 172B, which is arranged on a side of the carrier substrate 170 facing away from the semiconductor layer stack 2.

In this exemplary embodiment, the second contact area 162A and the second connection area 172A may have an identical circular shape. The first contact area 161A and the first connection area 171A may have an identical circular ring shape.

The first device electrode 171B and the second device electrode 172B are arranged at the rear side 1B.

In addition, the laser diode component 1 may have any of the features, characteristics and advantages mentioned in connection with the further exemplary embodiments.

The scope of protection of the invention is not limited to the examples given hereinabove. The invention is embodied in each novel characteristic and each combination of characteristics, which particularly includes every combination of any features which are stated in the claims, even if this feature or this combination of features is not explicitly stated in the claims or in the examples.

This patent application claims the priority of German patent application 102022131374.3, the disclosure content of which is hereby incorporated by reference.

### REFERENCES

1 laser diode component
1A front side, radiation exit side
1B rear side
2 semiconductor layer stack
2A first main surface
2B second main surface
2C side surface
3 first semiconductor region
4 active region
5 second semiconductor region
7 insulating layer
8 terminal layer
11 dielectric layer
12 first recess
13 second recess
14 aperture
15 mirror layer
17 carrier
18 first contact means
19 second contact means
20 separation trench
30 projecting area of the first semiconductor region
33 unintentionally doped layer
34 n-doped layer
35A cut-off corner
70 opening
91 first contact layer
92 second contact layer
110 first part of dielectric layer
111 second part of dielectric layer
161 first contact post
161A first contact area
162 second contact post
162A second contact area
170 carrier substrate
171 first connection means
171A first connection area
171B first device electrode
171C first via
172 second connection means
172A second connection area
172B second device electrode
172C second via
173 isolation layer
2′ semiconductor layer sequence
2A′, 20′ outer surface
3′ first semiconductor layer
4′ active layer
5′ second semiconductor layer
6′ growth substrate
7′ mask layer
8′ terminal layer structure
10′ interspace
12′ first recess
13′ second recess
14′ aperture
15′ mirror layer structure
16′ contact post structure
17′ carrier structure
18′ first contact means structure
19′ second contact means structure
30′ projecting area of the first semiconductor layer
31′ n-doped current spreading layer
32′ highly n-doped sacrificial layer
33′ unintentionally doped layer
34′ n-doped layer
35′ upper region
35A′ cut-off corner
36′ lower region
60′ laterally projecting area of growth substrate
70′ opening
90′ contact layer structure
91′ first part
92′ second part
110′ first dielectric layer structure
111′ second dielectric layer structure
161′ first part
161A′ first contact area
162′ second part
162A′ second contact area
170′ carrier substrate structure
171′ first connection means structure
171A′ first connection area
172′ second connection means structure
172A′ second connection area
d thickness
A centre axis
L1 first lateral direction
L2 second lateral direction
V vertical direction

1. A laser diode component comprising
a semiconductor layer stack comprising:
a first semiconductor region,
a second semiconductor region and
an active region for emitting laser radiation, wherein the active region is arranged between the first semiconductor region and the second semiconductor region and wherein the first semiconductor region has a projecting area, where the first semiconductor region laterally projects beyond the active region and the second semiconductor region,
a dielectric layer covering the semiconductor layer stack,
first contact means for electrically contacting the first semiconductor region, comprising:
a first contact layer covering the projecting area of the first semiconductor region, and
a first contact post, which is arranged on a side of the first contact layer facing away from the first semiconductor region,
second contact means for electrically contacting the second semiconductor region, comprising:
a terminal layer partly covering the second semiconductor region,
a second contact layer laterally surrounding the terminal layer, and
a second contact post which is arranged on a side of the second contact layer facing away from the second semiconductor region, wherein
a first contact area of the first contact post laterally surrounds a second contact area of the second contact post, and
a carrier including first connection means and second connection means, wherein a first connection area of the first connection means is connected to the first contact area of the first contact means and a second connection area of the second connection means is connected to the second contact area of the second contact means, wherein the first connection area laterally surrounds at least partly the second connection area.

2. The laser diode component according to claim 1, wherein a separation trench between the first contact post and the second contact post has the shape of a circular ring.

3. The laser diode component according to claim 1, wherein the first contact area and the second contact area each have a rotationally symmetrical shape with respect to a centre axis of the laser diode component.

4. The laser diode component according to claim 1, wherein the second contact layer and the terminal layer each have a rotationally symmetrical shape with respect to a centre axis of the laser diode component.

5. The laser diode component according to claim 1, which comprises an insulating layer, wherein the insulating layer partly covers the second semiconductor region and comprises an opening, where the terminal layer is arranged and contacts the second semiconductor region.

6. The laser diode component according to claim 1, wherein the second semiconductor region and the active region do not laterally project beyond the insulating layer.

7. The laser diode component according to claim 1, wherein the dielectric layer is arranged at least partly on all outer surfaces of the semiconductor layer stack.

8. The laser diode component according to claim 1, wherein the dielectric layer forms a laser resonator of the laser diode component.

9. The laser diode component according to claim 1, wherein the dielectric layer comprises an aperture at a side surface of the semiconductor layer stack.

10. (canceled)

11. The laser diode component according to claim 1, wherein the semiconductor layer stack is arranged on the carrier in such a way that the second semiconductor region faces the carrier.

12. The laser diode component according to claim 1, which comprises a first device electrode and a second device electrode for electrically contacting the laser diode component from outside, wherein the first device electrode is a part of the first connection means and the second device electrode is a part of the second connection means.

13. The laser diode component according to claim 1, wherein the laser radiation is emitted mainly on a front side of the laser diode component facing away from the carrier.

14. The laser diode component according to claim 1, wherein the semiconductor layer stack is essentially free of a growth substrate.

15. A method for producing a laser diode component according to claim 1, the method comprising:
providing a semiconductor layer sequence for producing at least one semiconductor layer stack, the semiconductor layer sequence comprising:
a first semiconductor layer,
a second semiconductor layer and
an active layer for emitting laser radiation, wherein the active layer is arranged between the first semiconductor layer and the second semiconductor layer,
applying a mask layer on parts of the second semiconductor layer,
applying a terminal layer structure on parts of the second semiconductor layer for producing at least one terminal layer,
patterning the semiconductor layer sequence by means of the mask layer in such a way that the first semiconductor layer has at least one projecting area, where the first semiconductor layer laterally projects beyond the active layer and the second semiconductor layer,
applying a contact layer structure for producing at least one first contact layer and at least one second contact layer on the at least one projecting area of the first semiconductor layer and on the second semiconductor layer in such a way that the contact layer structure laterally surrounds the terminal layer structure,
applying a first dielectric layer structure on the semiconductor layer sequence in order to produce a first part of at least one dielectric layer,
applying a contact post structure on the first dielectric layer structure in such a way that a first contact area of at least one first part of the contact post structure provided for producing at least one first contact post laterally surrounds a second contact area of at least one second part of the contact post structure provided for producing at least one second contact post, and
providing a carrier structure for producing at least one carrier, wherein the carrier structure comprises first connection means and second connection means structures, which result in first connection means and second connection means, and
connecting the first connection means structure to a first contact means structure including the at least one first part of the contact post structure and connecting the second connection means structure to a second contact means structure including the at least one second part of the contact post structure.

16. The method according to claim 1, wherein
the semiconductor layer sequence is provided on a growth substrate and comprises a highly doped sacrificial layer facing the growth substrate,
in a first subsequent patterning step following the patterning of the second semiconductor layer and the active layer, the first semiconductor layer is patterned in such a way that an upper region and a lower region are produced, wherein the highly doped sacrificial layer terminates the lower region on a side facing the growth substrate, and
in a second subsequent step, the lower region is patterned in such a way that the growth substrate projects laterally beyond the lower region in a laterally projecting area.

17. The method according to claim 1, comprising:
providing the first dielectric layer structure in such a way that it covers the laterally projecting area of the growth substrate and comprises an aperture at a cut-off corner of the upper region, and
removing the highly doped sacrificial layer by an etchant introduced via the at least one aperture, wherein
the first dielectric layer structure forms a tether structure in the laterally projecting area of the growth substrate, which tether structure holds the semiconductor layer sequence to the growth substrate after removal of the sacrificial layer.

18. The method according to claim 1, comprising:
applying the carrier structure on a side of the semiconductor layer sequence facing away from the growth substrate, and
removing the growth substrate by detaching the tether structure.

19. The method according to claim 1, comprising: applying a second dielectric layer structure on a side of the semiconductor layer sequence facing away from the carrier structure in order to produce a second part of the at least one dielectric layer.

20. The laser diode component according to claim 1, wherein the first contact area and the first connection area have a ring shape and the second contact area and the second connection area have a circular shape.
